(19) United States
(12) Patent Application Publication
(10) Pub. No.: US 2006/0154435 A1
(43) Pub. Date: Jul. 13, 2006

(54) METHOD OF FABRICATING TRENCH ISOLATION FOR TRENCH-CAPACITOR DRAM DEVICES

(76) Inventors: Hsiu-Chun Lee, Taipei City (TW); Tse-Yao Huang, Taipei City (TW); Yinan Chen, Taipei City (TW)

Correspondence Address: NORTH AMERICA INTELLECTUAL PROPERTY CORPORATION, P.O. BOX 506, MERRIFIELD, VA, 22116, US

(21) Appl. No.: 10/907,101

(22) Filed: Mar. 20, 2005

(30) Foreign Application Priority Data
Jan. 11, 2005 (TW) 094100726

(51) Int. Cl. H01L 21/20

(52) U.S. Cl. 438/396

(57) ABSTRACT

A method of fabricating trench isolation for trench-capacitor DRAM devices. After the formation of deep trench capacitors, an isolation trench is etched into a substrate. The isolation trench is initially filled with a first insulating layer, which is then recessed into the isolation trench to a depth that is lower than the substrate main surface. An epitaxial layer is grown from the exposed sidewalls of the isolation trench. The isolation trench is then filled with a second insulating layer.

### BACKGROUND OF INVENTION

1. Field of the Invention

The present invention relates to a process for fabricating a semiconductor device. More particularly, the present invention relates to a process for fabricating trench isolation for trench-capacitor dram devices.

2. Description of the Prior Art

As the size of a memory cell shrinks, the chip area available for a single memory cell becomes very small. This causes reduction in capacitor area and therefore becomes a challenge for chip manufacturers to achieve adequate cell capacitance. Trench-capacitor DRAM devices are known in the art. A trench-storage capacitor typically consists of a very-high-aspect-ratio contact-style hole pattern etched into the substrate, a thin storage-node dielectric insulator, a doped low-pressure chemical vapor deposition (LPCVD) polysilicon fill, and buried-plate diffusion in the substrate. The doped LPCVD silicon fill and the buried plate serve as the electrodes of the capacitor. A dielectric isolation collar in the upper region of the trench prevents leakage of the signal charge from the storage-node diffusion to the buried-plate diffusion of the capacitor.

In general, the prior art method for fabricating a trench capacitor of a DRAM device can be summarized as follows:

Phase 1: deep trench etching.

Phase 2: buried plate and capacitor dielectric formation.

Phase 3: first polysilicon deep trench fill and first recess etching.

Phase 4: collar oxide formation.

Phase 5: second polysilicon deposition and second recess etching.

Phase 6: collar oxide wet etching.

Phase 7: third polysilicon deposition and third recess etching.

Phase 8: active area definition and trench isolation process.

Please refer to FIG. 1. FIG. 1 is a plan view demonstrating the layout of a portion of a trench-capacitor DRAM device. As shown in FIG. 1, previously alluded to, after forming the trench capacitors 12 in the substrate 10, a photo resist pattern 20 is formed on the substrate 10. The photo resist pattern 20 defines active areas 20. In FIG. 1, the contour of the active areas 20 defined by the photo resist pattern 20 is indicated with dash line 22 before shallow trench isolation process. After the shallow trench isolation process, an average shrinkage of “d” of the active areas is observed. After the shallow trench isolation process, the contour of the shrunk active areas is indicated with bold line 24. This adversely affects the strictly requirement of the overlapping surface area between an active area 20 and corresponding trench capacitors 12.

### SUMMARY OF INVENTION

It is therefore to provide a novel trench isolation process for the trench-capacitor dram devices to solve the above-mentioned problem.

According to the claimed invention, a trench isolation process is disclosed. A semiconductor substrate having thereon a pad layer is provided. A photo resist layer is formed on the pad layer. The photo resist layer has an opening. Using the photo resist layer as a hard mask, the pad layer and the semiconductor substrate is etched through the opening of the photo resist layer, thereby forming a trench in the semiconductor substrate. The trench is then filled with a first insulating material layer. The first insulating material layer inside the trench is etched back to a depth such that a portion of the semiconductor substrate of sidewalls of the trench is exposed. An epitaxial process is then conducted to grow an epitaxial layer on the exposed portion of the semiconductor substrate of sidewalls of the trench. The trench is again filled with a second insulating material layer atop the first insulating material layer.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a plan view demonstrating the layout of a portion of a trench-capacitor DRAM device; and

FIG. 2 to FIG. 9 are schematic, cross-sectional diagrams illustrating the trench isolation process in accordance with one preferred embodiment of the present invention.

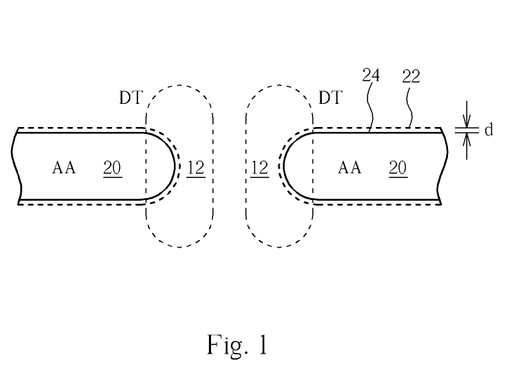

### DETAILED DESCRIPTION

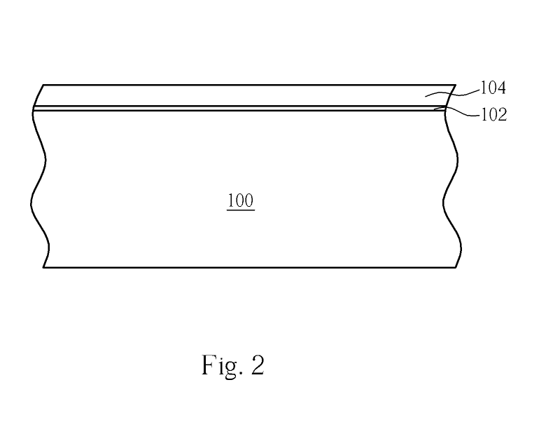

Please refer to FIG. 2 to FIG. 9. FIG. 2 to FIG. 9 are schematic, cross-sectional diagrams illustrating the trench isolation process in accordance with one preferred embodiment of the present invention. As shown in FIG. 2, a semiconductor substrate 100 is provided with a number of deep trench capacitors (not shown) formed therein. A pad oxide layer 102 and a pad silicon nitride layer 104 are formed on the surface of the substrate 100.

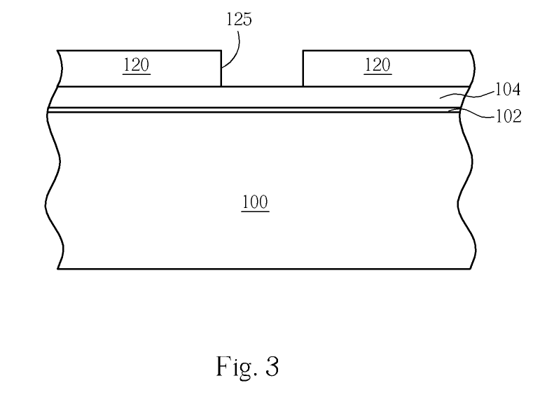

As shown in FIG. 3, a photo resist pattern 120 that defines active areas is formed over the pad silicon nitride layer 104. The photo resist pattern 120 also defines trench isolation areas through opening 125. The pattern of the isolation trench to be etched into the substrate surface is exposed through the opening 125.

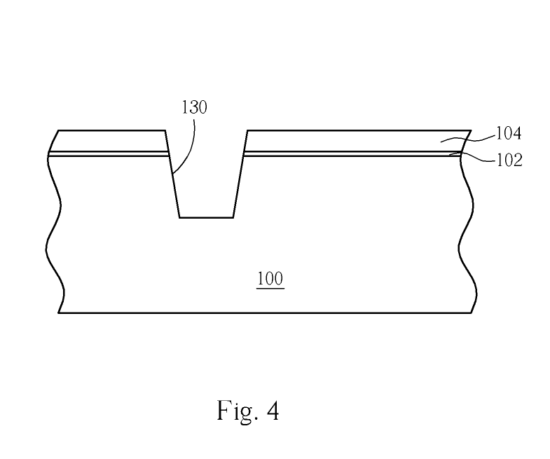

As shown in FIG. 4, using the photo resist pattern 120 as an etching hard mask, a dry etching process is conducted to etch the exposed pad silicon nitride layer 104, the pad oxide layer 102, and the semiconductor substrate 100 through the opening 125, thereby forming a trench 130. The photo resist pattern 120 is then removed using any suitable methods known in the art.

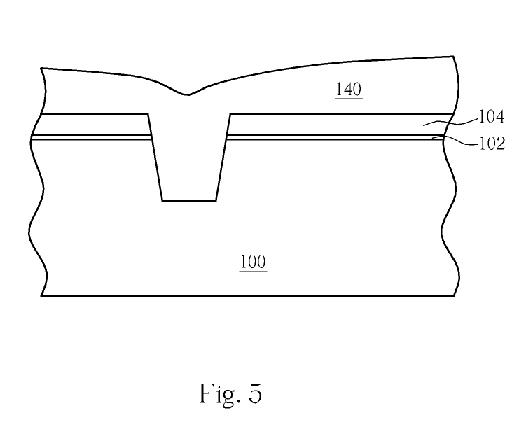

As shown in FIG. 5, a chemical vapor deposition (CVD) process such as high-density plasma CVD process is carried out to deposit a blanket silicon oxide film 140 over the semiconductor substrate 100. The silicon oxide film 140 fills the trench 130.

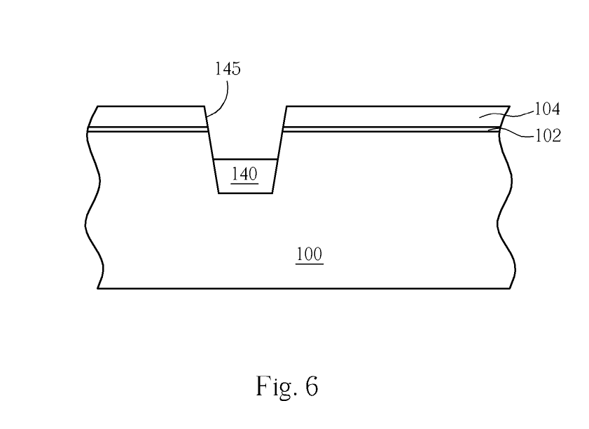

Subsequently, as shown in FIG. 6, using the pad silicon nitride layer as a hard mask, a dry etching process is performed to etch away the silicon oxide film 140 outside the trench 130 and continues to etch the silicon oxide film 140 inside the trench to a depth such that a portion of the semiconductor substrate 100 of the trench sidewalls is exposed. At this phase, a recess 145 is produced at an upper portion of the trench 130.

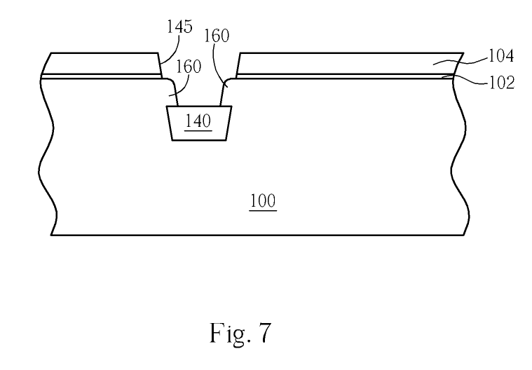

As shown in FIG. 7, an epitaxial silicon layer 160 is grown on the exposed semiconductor substrate 100 of the trench sidewalls by using a suitable eptitaxial method known in the art. According to this invention, the conductivity of the epitaxial silicon layer 160 is the same as the semiconductor substrate 100, for example, P type. According to the preferred embodiment, the epitaxial silicon layer 160 has a thickness of about 5-50 angstroms. This thickness compensates the previous loss of the active areas during the etching.

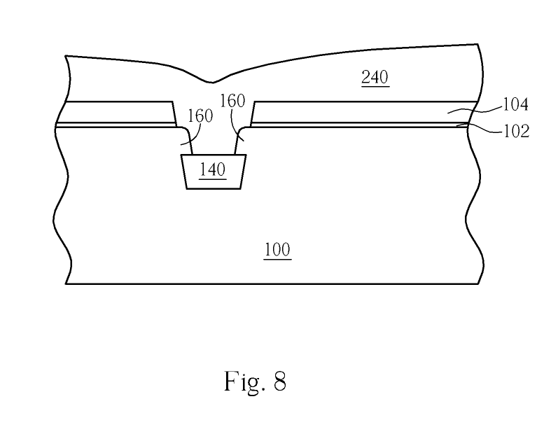

As shown in FIG. 8, another blanket chemical vapor deposition process is performed to fill the recess 145 with a high-density plasma oxide film 240. The high-density plasma oxide film 240 also covers the pad silicon nitride layer 104 as indicated.

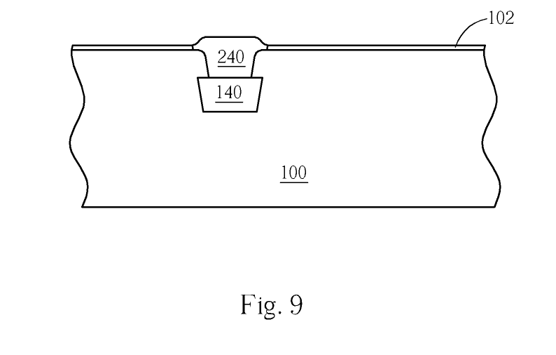

As shown in FIG. 9, lastly, using the pad silicon nitride layer 104 as a polish stop layer, a chemical mechanical polishing process is carried out to planarize the high-density plasma oxide film 240. The remaining pad silicon nitride layer 104 not removed in the CMP process may be etched away in a later wet etching process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A trench isolation process comprising:
providing a semiconductor substrate having thereon a pad layer;
forming a photo resist layer on the pad layer, wherein the photo resist layer has an opening;
using the photo resist layer as a hard mask to etch the pad layer and the semiconductor substrate through the opening of the photo resist layer, thereby forming a trench in the semiconductor substrate;
filling the trench with a first insulating material layer;
etching back the first insulating material layer inside the trench to a depth such that a portion of the semiconductor substrate of sidewalls of the trench is exposed;
conducting an epitaxial process to grow an epitaxial layer on the exposed portion of the semiconductor substrate of sidewalls of the trench; and
filling the trench with a second insulating material layer atop the first insulating material layer.

2. The trench isolation process according to claim 1 wherein after filling the trench with a second insulating material layer atop the first insulating material layer, the trench isolation process further comprises the following steps:
performing a chemical mechanical polishing process and using the pad layer as a polish stop layer to planarize the second insulating material layer; and
removing the pad layer.

3. The trench isolation process according to claim 1 wherein the pad layer comprises silicon nitride.

4. The trench isolation process according to claim 1 wherein the first insulating material layer comprises silicon oxide.

5. The trench isolation process according to claim 1 wherein the second insulating material layer comprises silicon oxide.

6. The trench isolation process according to claim 1 wherein the epitaxial layer has thickness of about 5-50 angstroms.

7. The trench isolation process according to claim 1 wherein the epitaxial layer has conductivity that is the same as that of the semiconductor substrate.
